(19) United States
(12) Patent Application Publication
(10) Pub. No.: US 2007/0187710 A1
(43) Pub. Date: Aug. 16, 2007

(54) Led light source

(75) Inventors: Ronald L. Steen, Lindenhurst, IL (US); Kyle P. Lucas, Clawson, MI (US)

Correspondence Address: WARN, HOFFMANN, MILLER & LALONE, .P.C, PO BOX 70098, ROCHESTER HILLS, MI, 48307, US

(73) Assignee: Schefenacker Vision Systmes USA Inc., Marysville, MI (US)

(21) Appl. No.: 10/568,927

(22) PCT Filed: Sep. 7, 2004
(86) PCT No.: PCT/US04/28847

§ 371 Date: Mar. 20, 2007

Related U.S. Application Data
(60) Provisional application No. 60/500,980, filed on Sep. 8, 2003.

(51) Int. Cl. H01L 33/00; H01L 29/24

(52) U.S. Cl. 257/100

(57) ABSTRACT

An LED unit (20) having increased light output. The LED unit (20) includes a submount substrate (22) having a cavity (24). An LED chip (30) is electrically mounted within the cavity (24) and a phosphor layer (34) is deposited in the cavity (24) that converts blue light from the LED chip (30) into white light suitable for a vehicle headlight (10). The walls of the cavity (24) are metalized (40) to increase the light output intensity. In one embodiment, a clear protective layer (46) is deposited in the cavity (24) over the phosphor layer (34).

### BACKGROUND OF THE INVENTION

1. Field of the Invention

This invention relates generally to an LED light source and, more particularly, to an LED light source that includes an LED chip mounted within a cavity formed in a substrate, and a phosphor layer deposited in the cavity to encapsulate the LED chip.

2. Discussion of the Related Art

Vehicle styling and appearance provides significant and important advantages for attracting customers. One recognized area that is known to enhance vehicle attraction is the appearance and design of the various vehicle lights, sometimes referred to as the vehicle's jewels, including, but not limited to, headlights, tail lights, turn signals, back-up lights, center high mounted stop lamps (CHMSLs), running lights, fog lamps, side markers, etc. In fact, modern vehicle designs pay close attention to the styling and design of the vehicle lights.

Current vehicle lights employ various types of light sources suitable for different designs and conditions. For example, vehicle lighting designs have employed incandescent lamps, neon tubes, halogen lamps, xenon lamps, etc. Some modern vehicle light designs have employed light emitting diodes (LEDs) that are able to provide various colors in an inexpensive and compact arrangement. LEDs typically do not suffer from burn-out, and have good drive characteristics, high luminance, high efficiency, high vibration resistance and durability to endure repetitive on/off operations. Therefore, LEDs have been attractive for vehicle lighting.

LEDs emit monochromatic light at wavelengths depending on the doping characteristics of the LED semiconductor material. Traditionally, the most efficient LEDs have emitted red light, green light or blue light. It has heretofore not been possible to provide an LED semiconductor material that emits white light. However, various LED designs are available that convert colored light to white light. One design employs a combination of red, green and blue LEDs arranged close together. The light from the LEDs is combined and diffused to provide the white light. However, these types of LED designs have typically been limited because of variances in tone, luminance and drive power of the different LEDs.

Another white light LED design employs a colored light LED and a fluorescent material that absorbs the colored light and emits white light. U.S. Pat. No. 6,069,440, issued May 30, 2000 to Shimizu et al., discloses a white light LED including a layer of phosphor deposited over a blue light LED. The phosphor includes a fluorescent that absorbs the blue wavelength light and emits white light. In one particular design, the LED material is InGaN and the phosphor layer includes an yttrium-aluminum-garnet fluorescent material.

There is a push in the automotive industry to develop white light LEDs so that LEDs can be used in vehicle headlights. Important design concerns for vehicle headlights come into play when using the existing technology for generating white light from LED semiconductors, such as employing blue LEDs in combination with a phosphor layer. Particularly, intensity and directional considerations are important for the tightly regulated headlight requirements. Further, providing a compact, efficient, low cost and aesthetically pleasing LED package is necessary.

Improvements can be made in LED units to enhance or increase the light output from the LEDs.

### SUMMARY OF THE INVENTION

In accordance with the teachings of the present invention, an LED unit is disclosed that provides an increased light output. The LED unit includes a submount substrate mounted to a main substrate. The submount substrate includes a cavity in which an LED chip is electrically mounted. The remaining portion of the cavity is filled with a phosphor material that converts blue light from the LED chip to white light suitable for a vehicle headlight. The sides of the cavity can be metalized so that the light emitted from the LED unit is reflected therefrom.

Additional advantages and features of the present invention will become apparent from the following description and appended claims, taken in conjunction with the accompanying drawings.

### BRIEF DESCRIPTION OF THE DRAWINGS

FIG. 1 is a broken-away, perspective view of an LED headlamp mounted to a vehicle body panel;

FIG. 2 is a top view of an LED unit, according to an embodiment of the present invention;

FIG. 3 is a cross-sectional view through line 3-3 oft he LED unit shown in FIG. 1;

FIG. 4 is a cross-sectional view of an LED unit, according to another embodiment of the present invention; and

FIG. 5 is a top view of an LED unit, according to another embodiment of the present invention.

### DETAILED DESCRIPTION OF THE EMBODIMENTS

The following discussion of the embodiments of the invention directed to an LED light source is merely exemplary in nature, and is in no way intended to limit the invention or its applications or uses. For example, the following discussion describes the LED unit as being applicable for a vehicle headlamp. However, as will be appreciated by those skilled in the art, the LED unit of the invention has application in many other environments.

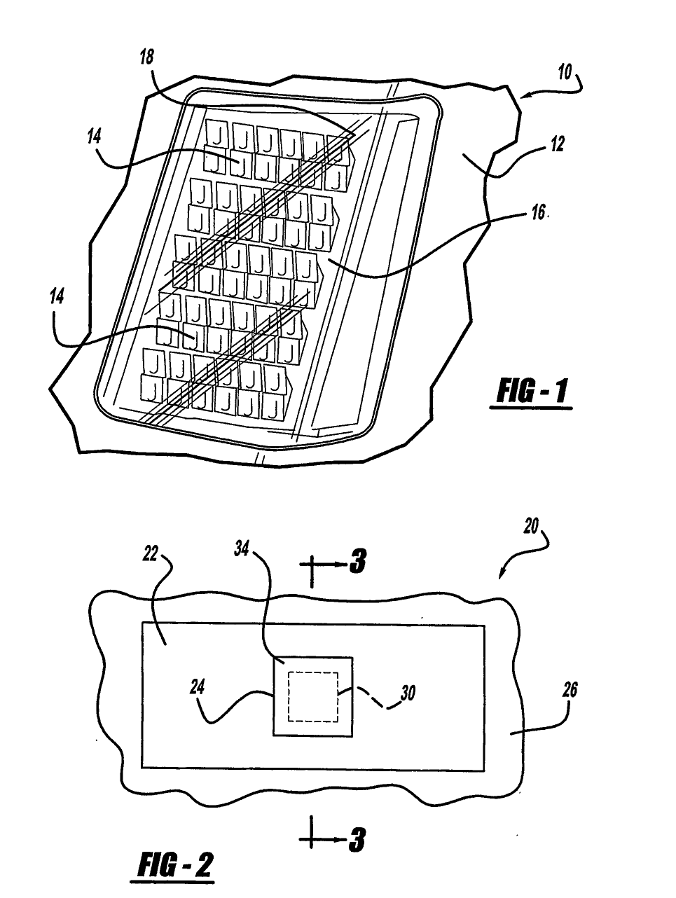

FIG. 1 is a broken-away, perspective view of a vehicle headlamp 10 mounted to a vehicle body panel 12. The vehicle headlamp 10 includes a series of LED headlamp assemblies 14 mounted to a common carrier 16. The LED assemblies 14 are enclosed within a sealed compartment defined by an outer lens 18. The LED assemblies 14 include one or more LEDs that generate white light.

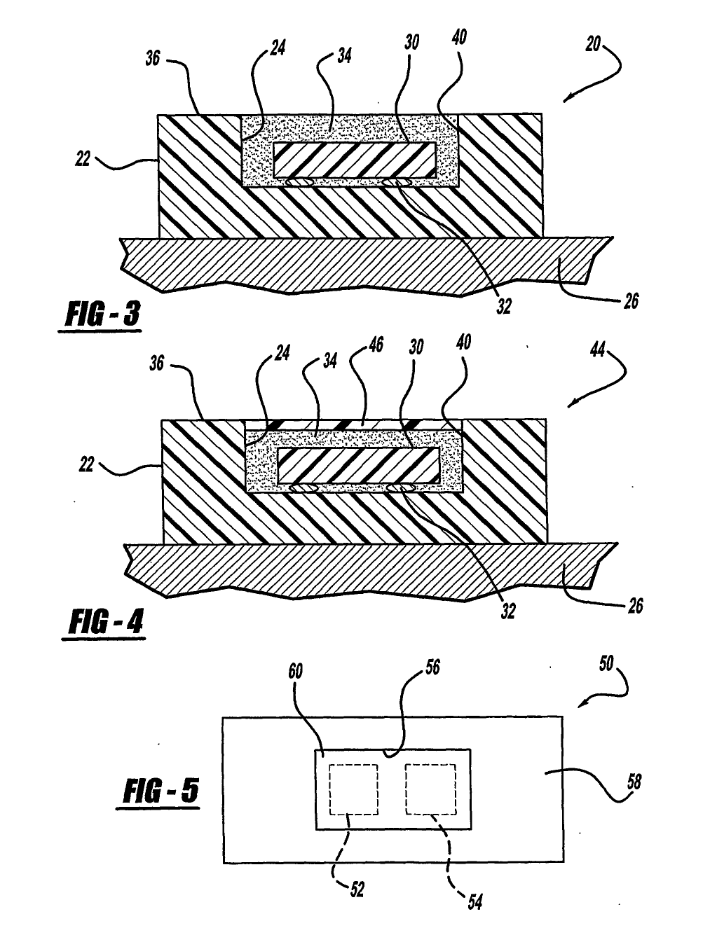

FIG. 2 is a top view and FIG. 3 is a cross-sectional view through line 3-3 of an LED unit 20, according to an embodiment of the present invention. The LED unit 20 can be one of several LED units within each LED assembly 14. The LED unit 20 includes a submount substrate 22 in which a cavity 24 has been formed by any suitable process. In one embodiment, the submount substrate 22 is made of aluminum nitride (AIN), however, this is by way of a non-limiting example. The cavity 24 would be formed in the AIN submount substrate 22 by a suitable masking and etching process, as would be appreciated by those skilled in the art. The submount substrate 12 is mounted to a main substrate 26, where several other LED units (not shown) can be mounted to form an LED unit array. In one embodiment, the main substrate 26 is the carrier 16 of the headlamp 10.

The LED unit 20 includes an LED chip 30 electrically mounted within the cavity 24. In this embodiment, the LED chip 30 is mounted to the substrate 22 by “chip-on-board” technology that provides an electrical connection to the submount substrate 22 by solder or stud bumps 32. Once the LED chip 30 is mounted within the cavity 24, a phosphor layer 34 is deposited within the cavity 24 to completely encapsulate the LED chip 30. In one embodiment, phosphor is placed on a top surface 36 of the submount substrate 22, and then a squeegee is used to push it into the cavity 24 so a top surface 38 of the phosphor layer 34 is flushed with the top surface 36 of the submount substrate 22. The opening of the cavity 24 defines the source size of the LED unit 20.

In one embodiment, the walls of the cavity 24 are metalized with a suitable metal layer 40, such as aluminum, silver, etc. This provides better light scattering and reflection for higher beam output. Also, in this embodiment, the walls of the cavity 24 are straight, i.e., at 90° relative to the top surface 36. However, in alternate designs, the walls of the cavity 24 can be flared out at a predetermined angle to provide a desirable light reflection therefrom.

In this embodiment, the LED 30 emits blue light, and the phosphor layer 34 converts the blue light to white light in a manner that is well known to those skilled in the art. The thickness of the phosphor layer 34 defines the color of the light emitted from the unit 20. Particularly, if the thickness of the phosphor layer 34 is too thin, then the light will be more yellow. Likewise, if the thickness of the phosphor layer 34 is too thick, then the light will be more blue. Alternately, the LED 30 can be replaced with a UV LED and the phosphor layer 34 can be a red, green, blue phosphor layer to provide the white light.

The cavity 24 provides a well-defined shape for the phosphor layer 34, where the sides of the phosphor layer 34 do not affect the directionality of the light beam. Further, by confining the phosphor layer 34 in the cavity 24, the light from the LED chip 30 is homogenized to even out the light output. Also, the light output of the LED chip 30 is easier to model. By controlling the shape, size and dimensions of the phosphor layer 34 within the cavity 24, the optical quality of the light beam is increased.

In one embodiment, the submount substrate 22 is approximately 2×2 mm square having a height of about 1.05 mm. The cavity 24 is a 1.2×1.2 mm square having a depth of approximately 0.7 mm. The LED chip 30 is approximately 1×1 mm square.

In an alternate embodiment, the cavity 24 can be only partially filled with the phosphor layer 34 to the desired thickness. FIG. 4 is a cross-sectional view of an LED unit 44 depicting this embodiment of the invention, where like elements are identified by the same reference numeral. The LED unit 44 includes a clear layer 46 deposited in the cavity 24 on top of the phosphor layer 34. The clear layer 46 can be a silicon layer, or any other suitable material, that provides a protective and inactive layer, but seals the phosphor layer 34 from the environment.

In order to increase the output intensity of the LED unit 20, it is possible to provide more than one LED chip in the cavity 24. FIG. 5 is a top view of an LED unit 50, similar to the LED unit 20, that includes two LED chips 52 and 54 formed within a cavity 56 of a submount substrate 58. A phosphor layer 60 fills the cavity 56 to encapsulate both of the LED chips 52 and 54. In this embodiment, the chips 52 and 54 are both 1×1 mm square, and the length of the cavity 56 is increased to 2.3 mm to accommodate both of the chips 52 and 54.

The foregoing discussion discloses and describes merely exemplary embodiments of the present invention. One skilled in the art will readily recognize from such discussion and from the accompanying drawings and claims, that various changes, modifications and variations can be made therein without departing from the spirit and scope of the invention as defined in the following claims.

What is claimed is:

1. An LED unit comprising:
a substrate including a cavity;
at least one LED chip mounted within the cavity; and
a phosphor layer deposited within the cavity and encapsulating the LED chip.

2. The unit according to claim 1 wherein a top surface of the phosphor layer is substantially even with a top surface of the substrate.

3. The unit according to claim 1 further comprising a clear layer deposited in the cavity on top of the phosphor layer.

4. The unit according to claim 3 wherein a top surface of the clear layer is substantially even with a top surface of the substrate.

5. The unit according to claim 3 wherein the clear layer is silicon.

6. The unit according to claim 1 wherein walls of the cavity are metalized to provide an increased light reflection therefrom.

7. The unit according to claim 1 wherein walls of the cavity are tapered.

8. The unit according to claim 1 further comprising a base substrate that accommodates a plurality of LED units.

9. The unit according to claim 1 wherein the at least one LED chip is a 1×1 mm square LED chip and the cavity is a 1.2×1.2 mm square cavity.

10. The unit according to claim 1 wherein the at least one LED chip is two LED chips.

11. The unit according to claim 10 wherein the two LED chips are square chips.

12. The unit according to claim 11 wherein the LED chips are 1×1 mm square LED chips.

13. The unit according to claim 1 wherein the LED unit is part of a vehicle headlight.

14. A vehicle headlight comprising:
a base substrate a cavity; and
a plurality of LED units mounted to the base substrate in a predetermined pattern, each LED unit including a sub-mount substrate having a cavity, each LED unit including at least one LED chip mounted within the cavity and a phosphor layer deposited within the cavity and encapsulating the LED chip.

15. The unit according to claim 14 wherein each LED unit further includes a clear layer deposited in the cavity on top of the phosphor layer.

16. The unit according to claim 14 wherein walls of each cavity are metalized to provide an increased light reflection therefrom.

17. The unit according to claim 14 wherein walls of each cavity are tapered.

18. The unit according to claim 14 wherein the at least one LED chip is two LED chips.

19. A method of making an LED unit, said method comprising:
providing a substrate;
forming a cavity in the substrate;
electrically mounting at least one LED chip within the cavity; and
depositing a phosphor layer within the cavity to encapsulate the LED chip.

20. The method according to claim 19 further comprising depositing a clear layer in the cavity on top of the phosphor layer.

21. The method according to claim 19 further comprising depositing metal layer on walls of the cavity to increase light reflection therefrom.

22. The method according to claim 19 wherein forming a cavity includes forming walls of the cavity to be tapered.

23. The method according to claim 19 wherein mounting the at least one LED chip includes mounting two LED chips within the cavity.
